(19) United States
(12) Patent Application Publication
(10) Pub. No.: US 2006/0228855 A1
(43) Pub. Date: Oct. 12, 2006

(54) Capacitor with co-planar electrodes

(75) Inventors: Yongki Min, Phoenix, AZ (US); Cengiz A. Palanduz, Chandler, AZ (US)

Correspondence Address: MCANDREWS HELD & MALLOY, LTD, 500 WEST MADISON STREET, SUITE 3400, CHICAGO, IL, 60661, US

(73) Assignee: Intel Corporation

(21) Appl. No.: 11/092,357

(22) Filed: Mar. 29, 2005

(51) Int. Cl. H01L 21/8242

(52) U.S. Cl. 438/240; 438/250

(57) ABSTRACT

Methods and structures related to film capacitors are disclosed. The capacitors include electrodes in a side-by-side or laterally offset configuration instead of a usual stacked configuration. The side-by-side configuration allows the interposing of the dielectric layer between the capacitor electrodes to be formed without as stringent a fabrication environment as is conventional. The electrodes are platinum in an embodiment. The dielectric is barium strontium titanate in an embodiment.

### FIELD

The present disclosure relates to capacitor structures and methods for forming capacitors having co-planar electrodes.

### BACKGROUND

Integrated circuit structures, such as capacitors, continue to shrink in an attempt to use less electrical energy during operation, to fabricate more structures on each wafer, and to be housed in smaller packages. However, as the physical size of the integrated structures have shrunk the fabrication processes must be precisely controlled at the surface of each wafer to prevent defects in the thin films that construct the integrated circuits. In the case of decoupling capacitors, it is desirable to provide capacitors in close proximity to integrated circuit dies or chips. A capacitor can be formed on an interposer substrate that is connected between the integrated circuit die and package. This saves space on the integrated circuit die or package. This further improves capacitance used on signal lines and power supply lines.

One example of a capacitor is a thin film, vertically stacked capacitor as shown in FIG. 1. FIG. 1 shows a vertically stacked capacitor having a lower electrode 101, an upper electrode 102, and a ceramic, dielectric layer 104 formed directly on the upper surface of lower electrode 101. The lower surface of upper electrode 102 is formed on the upper surface of dielectric layer 104. Ideally, dielectric layer 104 vertically separates the lower electrode 101 and the upper electrode 102 such that their respective upper surface and lower surface are parallel and completely separated. The surfaces of the lower and upper electrodes are typically parallel to a surface of a supporting substrate. The separation of the lower and upper electrodes 101, 102 allows one electrode to store electrical charge relative to the other electrode. However, during fabrication a defect 105 is formed in the dielectric layer 104. Defect 105 can be caused by the dust from the environment and by imprecise processing conditions such as incorrect temperature, incorrect pressure, and incorrect component elements. Defect 105 can also be formed by relatively violent fabrication techniques such as sputtering that result in poor control of the composition of the final thin dielectric film.

In capacitive applications it is desirable to reduce the thickness of dielectric films to increase capacitive properties. Accordingly, the dielectric layer 104 is very thin relative to the electrode thicknesses. That is, the vertical separation of the electrodes 101, 102 is quite small relative to the horizontal area of the electrode surfaces. The defect 105 can be a pin hole or incomplete crystal structure through the dielectric layer such that a hole exists all the way through the dielectric layer. When the defect 105 exists through the dielectric layer 104, the conductive material forming the upper layer 102 fills the defect 105 and contacts the lower electrode 101. The defect 105 now is electrically conductive. In the case where the dielectric layer 104 is thin, the defect need not be very long to cause a short. As a result the upper electrode 102 is shorted to the lower electrode 101. Once the short exists the capacitor does not work. This defective integrated circuit structure will not perform as desired. If this defect is discovered prior to leaving the fabrication plant, then the integrated circuit structure may be repaired or scrapped, either way results in economic loss. Moreover, the materials, such as a metal, is easily oxidized at the high processing temperatures used in processing of material for dielectric layer 104. When a reducing atmosphere is used during processing of the dielectric layer 104, then the dielectric material may be reduced to a conductive state. At certain working electric fields, e.g., two volts, 0.1 micron, free charge carriers in the ceramic, dielectric material generated in a reducing atmosphere can migrate to an electrode causing space charge formation and accompanying Schottky emission of electrons from the cathode into the dielectric material to maintain charge neutrality. There is a need to reduce the defects in thin film capacitors. There is a further need to improve capacitors for attachment packages or interposers.

### BRIEF DESCRIPTION OF DRAWINGS

FIG. 1 shows a prior art capacitor with a defect.

FIG. 2 shows a side view of an assembly with an interposer substrate mounted between a die and a substrate.

FIGS. 3A, 3B and 3C show an interposer with a capacitor at various stages of fabrication according to an embodiment of the invention.

FIGS. 4A, 4B and 4C show a capacitor at various stages of fabrication with simplified cross hatching for clarity, according to an embodiment of the invention.

FIG. 5 shows a flow chart of a process according to an embodiment of the invention.

FIG. 6 shows a side view of a capacitor according to an embodiment of the invention.

FIG. 7 shows a top view of an array of capacitors according to an embodiment of the invention.

FIG. 8 shows an electrical system including a capacitor according to an embodiment of the invention.

FIG. 9 shows an electrical system including a capacitor according to an embodiment of the invention.

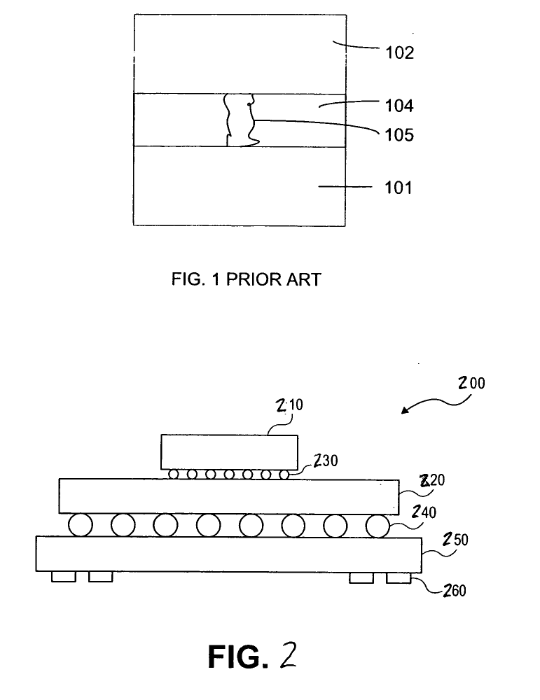

### DETAILED DESCRIPTION

In the following description, reference is made to the accompanying drawings that show, by way of illustration, specific embodiments in which the invention may be practiced. These embodiments are described in sufficient detail to enable those skilled in the art to practice the embodiments of the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled.

The present description uses the terms “top” and “back” when referring to the substrate on which capacitors as described herein are formed. The term “top” refers to the surface on which layers that form integrated circuit structures are formed. The term “back” refers to the region of the substrate beneath the surface on which circuit structures are formed.

The present description further uses the terms “upwardly”, “downwardly”, “horizontally”, and “vertically.” These terms refer to directions relative to the substrate and in some instances refer to the surface of the substrate on which additional thin films are fabricated. Such terminology will include the words specifically mentioned, derivatives thereof, and words of similar import.

It will be recognized that the cross-hatching in the figures does not designate any particular material and is provided for clarity of illustration.

FIG. 2 shows assembly 200 including die or chip 210, interposer substrate 220 and base substrate 250. The assembly may form part of an electronic system such as a computer (e.g., desktop, laptop, hand-held, server, etc.), a wireless communication device (e.g., cellular phone, cordless phone, pager), a computer-related peripheral (e.g., printer, scanner, monitor), an entertainment device (e.g., television, radio, stereo, tape player, compact disk player, video cassette recorder, digital audio/visual player and the like.

In the embodiment shown in FIG. 2, die 210 is an integrated circuit die, such as a processor die. Electrical contact points (e.g., contact pads) on a surface of die 210 are connected to interposer 220 through conductive bump layer 230. Base substrate 250 is, for example, a package substrate, that may be used to connect assembly 200 to a printed circuit board, such as a motherboard or other circuit board. Interposer 220 is electrically connected to base substrate 250 through conductive bump layer 240 that aligns, for example, contact pads on a surface of interposer 220 with contact pads on the surface of base substrate 250. FIG. 2 also shows surface mount capacitors 260 that may optionally be connected to base substrate 250.

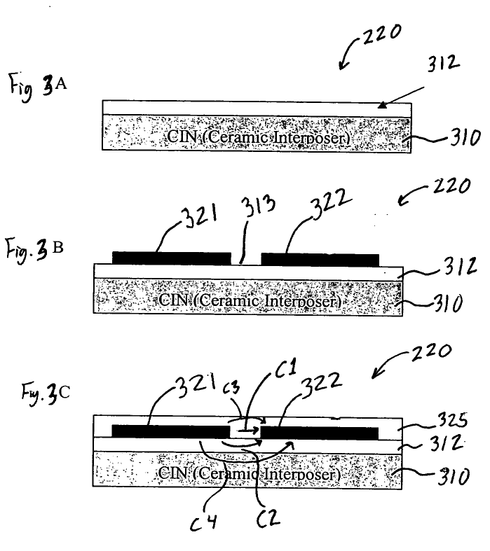

FIGS. 3A-3C show an embodiment of a thin-film co-planar capacitor formed on interposer 220 during various stages of fabrication. FIG. 3A shows an enlarged, partial view of interposer 220 with an interposer substrate 310 on which is formed a dielectric layer 312. In an embodiment, the interposer substrate 310 is a ceramic interposer substrate. Interposer substrate 310 is, for example, formed of a ceramic having a relatively low dielectric constant. A low dielectric constant (low-k) material is a ceramic material having a dielectric constant on the order of 10. Examples of low dielectric constant materials for use in the present application include, but are not limited to, a glass ceramic or aluminum oxide (e.g., Al₂O₃).

Dielectric layer 312, in an embodiment, is a high-k dielectric layer formed on the interposer substrate 310. A high-k dielectric has a high dielectric constant. In an embodiment, the dielectric layer 312 is a high-k ceramic that has a dielectric constant on the order of approximately 1000. In an embodiment, the dielectric constant is greater than 200. In an embodiment, the dielectric constant is greater than 225. In an embodiment, the dielectric constant is in a range of about 225 to about 250. Types of high-k dielectric materials include insulating inorganic metal oxide materials (such as ferroelectric materials, perovskite materials and pentoxides) are commonly referred to as “high k” materials due to their high dielectric constants, which make them attractive as dielectric materials in capacitors. In some embodiment, high-k may have a dielectric constant above about 20. In an embodiment, layer 312 includes strontium titanate (SrTiO₃). In an embodiment, layer 312 includes barium strontium titanate, BaSrTiO₃ (BST). In an embodiment, layer 312 includes barium titanate (BaTiO₃). Dielectric layer 312 is deposited by various techniques including physical vapor deposition, sputtering, chemical solution methods, green sheet technologies, screen printing, and chemical vapor deposition, and metal-organic decomposition (MOD). In an embodiment, layer 312 is about 60 angstroms thick. In an embodiment, layer 312 is about 0.1 to 2.0 microns thick.

Electrodes 321, 322 are formed on the top surface of dielectric layer 312. In an embodiment, the electrodes are formed from a patterned capacitive material. A gap 313 exists between adjacent electrodes 321, 322. As shown in FIGS. 3B and 3C the vertical dimension of the electrodes 321, 322 is significantly less than the horizontal dimension. In an embodiment, the vertical dimension (the z axis) is less than a order of magnitude relative to any horizontal dimension (the x, y axes). In an embodiment, the electrode includes a metal. In an embodiment, the electrode includes a noble metal. In an embodiment, the electrode includes platinum. In an embodiment, the electrode includes rhodium. In an embodiment, the electrode includes iridium In an embodiment, the electrode includes one of copper and nickel. In an embodiment, the electrode includes a metal nitride, e.g., TiN or WN. The material of the electrode is deposited using physical vapor deposition, e.g., sputtering, evaporation, etc. The patterning includes photolithography to create a photo-mask on a layer of electrode material. The layer of electrode material is then etched to remove portions of electrode layer to define electrodes 321, 322. Additional methods for patterning include lift-off techniques, hard mask techniques, and non-chemical techniques. As the electrodes 321, 322 are fabricated with gap 313 interposed between the electrodes, there is no conductive connection between the electrodes even if a defect exists in the later fabricated dielectric layer 312. The dielectric layer 312 will fill the gap 313. The electrodes 321, 322 are in the same structural layer in the fabrication process and formed at the same time in a laterally adjacent structure. Neither electrode 321, 322 has any portion thereof over or vertically above the other electrode. In an embodiment, electrode 321 and 322 are neither vertically above nor below each other, and are arranged such that the smallest area surface of electrode 321 is adjacent to the smallest area surface of electrode 322.

A further dielectric layer 325 is formed on the exposed upper surface of electrodes 321, 322, and exposed upper surface of the dielectric layer 312. Dielectric layer 325 fills the gap 313. The material of the dielectric layer 325 in the gap 313 forms the principal capacitor dielectric structure for the capacitor. In an embodiment, the dielectric layer interposes a dielectric wall having a high-k dielectric constant between electrodes 321 and 322. In an embodiment, dielectric layer 325 is a high-k dielectric layer. The material forming dielectric layer 325 is the same as the material of dielectric layer 312 in an embodiment. In an embodiment, the dielectric layer 325 is a high-k ceramic that has a dielectric constant on the order of approximately 1000. In an embodiment, layer 325 includes strontium titanate (SrTiO₃). In an embodiment, layer 325 includes barium strontium titanate, BaSrTiO₃ (BST). In an embodiment, layer 325 includes barium titanate (BaTiO₃). Dielectric layer 325 is deposited by various techniques including physical vapor deposition, sputtering, chemical solution methods, green sheet technologies, screen printing, and chemical vapor deposition, and metal-organic decomposition (MOD). It is further within the scope of the present invention to provide laminates of films containing the materials described herein with regard to layer 325. In an embodiment, layer 325 is over 2.0 microns thick. Even if defects exist in the dielectric layer 325, in particular in the portion of layer 325 filling gap 313, the electrodes 321, 322 were fabricated in a prior step. As a result the material of electrodes 321, 322, which material is conductive, will not fill defects in dielectric layer 325 to cause a short between the electrodes 321, 322.

FIG. 3C further shows the capacitance of the non-stacked, laterally adjacent capacitor formed by laterally adjacent electrodes 321, 322. The capacitance between electrodes 321, 322 is the sum of the capacitance C1 through dielectric layer 325 in gap 313, capacitance C2 through the dielectric layer 312 below the gap, the capacitance C3 through the dielectric layer 325 above the gap, capacitance C4 through the interposer substrate 310, which can be a ceramic. By manipulating the capacitive properties of the each of these layers, e.g., dielectric constant and thickness, the capacitor provides the desired capacitance for a select application.

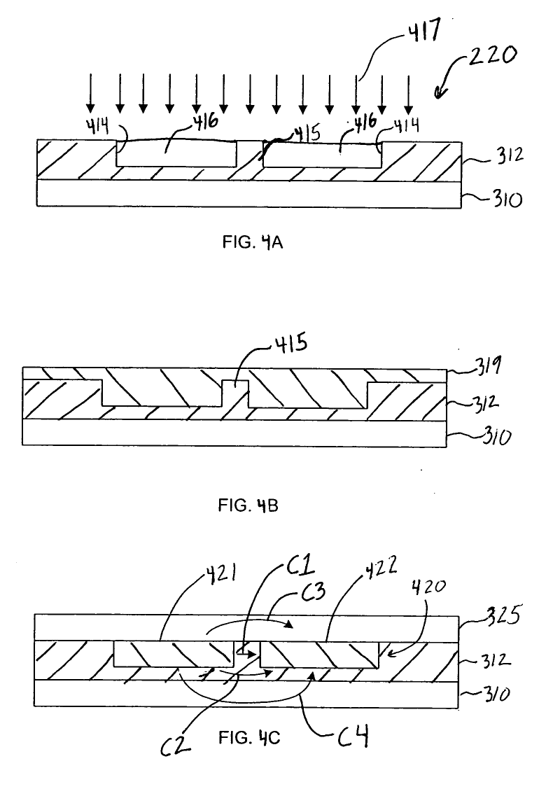

A further embodiment of a method for fabricating the interposer 220 with capacitor is now described. Recesses 414 are formed after dielectric layer 312 is deposited on the ceramic interposer substrate 310. Layer 312 is etched to form recesses 414 separated by a wall 415 of dielectric material. That is, the recesses and wall are formed by a negative (removal) process. While, FIG. 4A shows only two recesses for clarity of illustration, various embodiments include numerous recesses 414 to meet the capacitive needs of a particular application. The vertical surface 416 of dielectric layer 312 defines the recess 414. Surface 416 has greater dimensions in the horizontal plane than in the vertical plane. The recesses 414 are horizontally aligned and laterally adjacent. In an embodiment, the closed bottom of each recess 414 is at the same depth from the open top. The closed bottom of each recess 414 is separated from the top surface of the substrate 310 by a same thickness of dielectric material. The bottom surfaces of recesses 414 are positioned in a same plane defined by a downwardly recessed surface of layer 312. Wall 415 stands upwardly from the base portion of the layer 312 to separate two adjacent recesses 414. At this stage of processing, the wall 415 is supported only at a base portion of layer 312. The vertical side surface of wall 415 facing into a recess has significantly less area than the closed bottom of recess 414. In an embodiment, the area of the wall side surface is less than 10% of the area of the recess bottom. In an embodiment, the area of the wall side surface is over 100 times smaller than the area of the recess bottom.

In an embodiment, the recesses 414 and wall 415 are fabricated by a positive process. Such a process includes forming a base layer of dielectric layer 312 and forming sacrificial layers on the base layer at the recess locations. The process further forms the dielectric layer intermediate the sacrificial layer, specifically, wall 415 is formed. When the sacrificial layers are removed the recesses 414 and wall 415 remain on layer 312. The dielectric layer 312, including wall 415, can now be annealed in an oxygen environment prior to depositing the electrodes. In an embodiment, the electrodes include platinum. In an embodiment, the electrodes are essentially pure platinum.

A conductive material source 417 then forms a layer of conductive material on the dielectric layer 312 in such a way to fill the recesses 414. The material in recesses 414 will form capacitive electrodes 321, 322. The source 417 typically deposits capacitive material vertically toward the upper, fabrication surface of the substrate as shown in FIG. 4A and along the vertical surface of the wall 415 facing into the recess. The material fills from the bottom of recesses upwardly along the sides of recess defined by wall 415. As the recesses 414 are laterally adjacent (side-by-side) the recesses 414 fill with capacitive material at the same time. Examples of methods for depositing capacitive or conductive material include sputtering, physical vapor deposition, and chemical vapor deposition. If wall 415 has any defects, e.g., pinholes, discontinuities in the crystal structure, the conductive material may fill a vertical defect. However, due to the generally vertical application of the conductive material from source 417, the material from source 417 will not fill a horizontal defect, if any, extending between recesses 414 because to do so the horizontal defect would need to be at the top surface of wall 415. If any such defect existed at the very top of wall 415, it would be corrected when the conductive material is planarized off the upper surface of the entire substrate assembly or when the conductive material is patterned.

FIG. 4B shows the completed formation of an electrode layer 319 prior to patterning or planarization of the electrode layer to form the individual plates or electrodes 321, 322. In an embodiment, the electrode layer 319 includes a metal. In an embodiment, the metal includes a noble metal. In an embodiment, the metal includes rhodium. In an embodiment, the metal includes iridium. In an embodiment, the metal includes a metal nitride, e.g., TiN or WN. In an embodiment, the electrode layer 319 includes platinum. In an embodiment, the electrode layer 319 includes barrier layers in the recess and adjacent the wall 415 when necessary to prevent migration of elements from the dielectric layer 312 to the electrode layer 319. The material of layer 319 is planarized from the form shown in FIG. 4B to the form of separated electrodes or plates 321, 322 as shown in FIG. 4C. Specifically, the material of layer 119 is now only present in the recesses 414 to form the electrodes 321, 322 of a capacitor 420. A nonconductive top layer 325 is formed on the electrodes 321, 322 to further prevent shorts between the electrodes 321, 322.

Electrodes 321, 322 are laterally offset and adjacent to each other while being separated by wall 415. In an embodiment, the top surfaces of the electrodes 321, 322 are in a same plane that is essentially parallel to the upper surface of interposer substrate 310. In an embodiment, the bottom surfaces of the electrodes 321, 322 are in a same plane that is essentially parallel to the upper surface of substrate 310. Each electrode 321, 322 has a vertical dimension that is significantly less than the horizontal dimensions thereof. In an embodiment, the horizontal dimensions, i.e., the lateral dimension and into the paper dimension as shown in FIG. 4C, are at least an order of magnitude greater than the vertical dimension. In a further embodiment, the horizontal dimension is over 100 times the vertical dimension. In an embodiment, the vertical dimension is at least 200 nm. In an embodiment the vertical dimension is about 0.1 μm to about 0.2 μm. The capacitor 420 has electrodes 321 and 322 that are laterally offset from each other by the thickness of wall 415. The electrodes 321, 322 are not stacked. No part of any of electrode 321 is vertically above electrode 322. No part of any of electrode 322 is vertically above electrode 321. In an embodiment electrodes 321 and 322 are covered with a further high-k dielectric layer.

FIG. 4C further shows the capacitance of the non-stacked, laterally adjacent capacitor 120. The capacitance between electrodes 321, 322 is the sum of the capacitance C1 through wall 415, capacitance C2 through the dielectric layer 312 below the wall, the capacitance C3 through the insulator layer 325, capacitance C4 through the substrate 310 By manipulating the capacitive properties of the each of these layers, e.g., dielectric constant and thickness, the capacitor 120 provides the desired capacitance for a select application.

As a result of laterally offset position of electrodes 321, 322 with wall 415 extending therebetween, the conductive material will not short the electrodes 321, 322 together even when a vertical defect exists in the dielectric wall 415 between the electrodes 321, 322. Moreover, essentially vertically depositing the electrode material from source 417 prevents shorting the electrodes if a horizontal defect exists in the dielectric layer 415 as the conductive material is directionally deposited and will not travel far enough horizontally to completely fill a horizontal defect through the wall 415. That is, at least a portion of any horizontal defect will remain vacant and be a space filled with air or gas depending on the processing conditions of the particular process. Further, all of the conductive material on top of wall 415 is removed by patterning or planarization. In the event that that a defect exists at the very top of wall 415, the patterning or planarization will remove the conductive material and defect. The present disclosure provides a benefit over prior capacitors in integrated circuits. The present method frees the designer and/or fabrication from the strict constraints of fabrication techniques, e.g., pressure and temperature, when using high-k dielectrics.

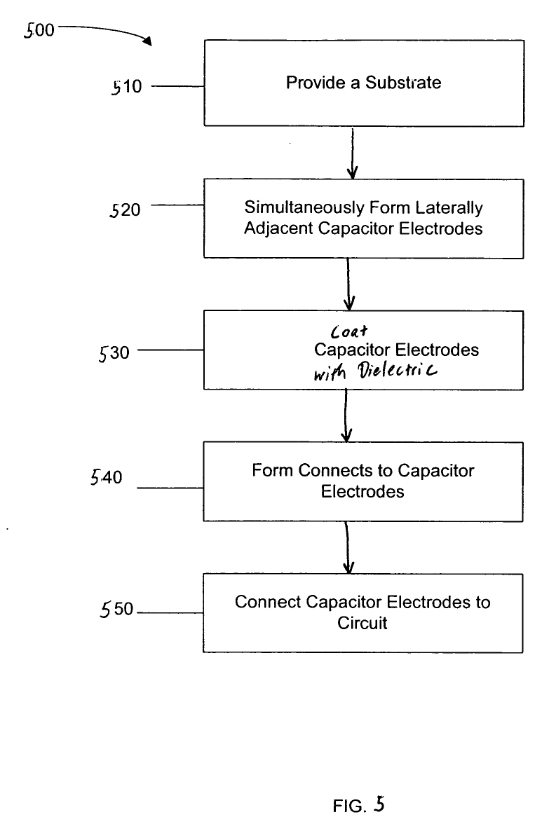

FIG. 5 shows a fabrication flowchart 500 according to an embodiment of the present process for fabrication of a side-by-side electrode capacitor. In step 510, an interposer substrate is prepared. The interposer substrate is adapted to provide off-die electrical functionality for digit or analog signal processing dies to which the interposer substrate will connect. In an embodiment, the electrical functions include input/output (I/O) functions. I/O functions for a capacitor include signal filtering, coupling, decoupling, etc. In step 520, laterally adjacent electrodes for a capacitor are formed on a dielectric layer on the interposer substrate. In an embodiment, the laterally adjacent electrodes have a dimension adjacent each other that is less than their lateral dimension. For example, the height of the FIGS. 3C and 4C capacitor is less than the lateral width. It will be appreciated that the electrodes are formed by negative process in an embodiment. In step 530, the capacitor electrodes are insulated or covered by a further dielectric material. Connections are formed to each of the electrodes, step 540. The connections are connected to other circuitry, step 550.

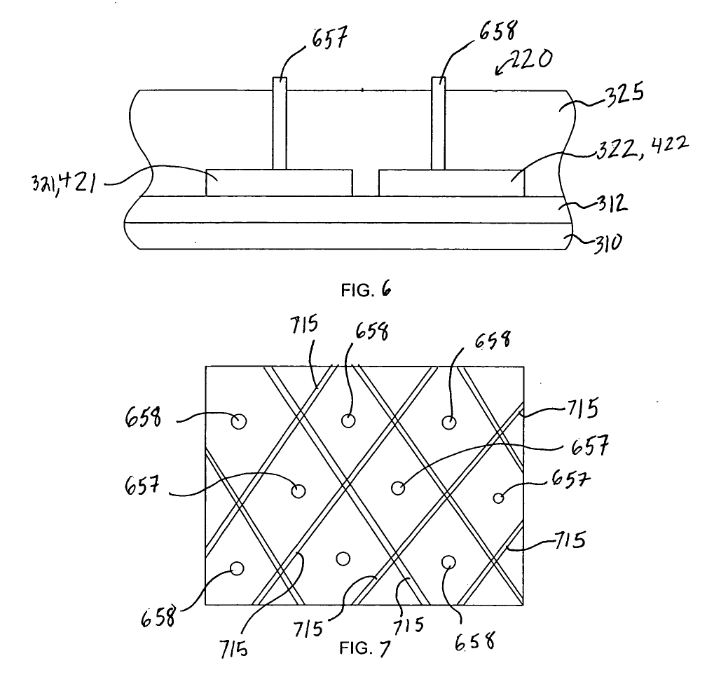

FIG. 6 shows an interposer with capacitor 220, according to an embodiment, having an dielectric layer 312 which is on an interposer substrate 310. Capacitor has a first electrode 321, 421 and a second electrode 322, 422 laterally adjacent to each other. The electrodes can be fabricated according to either the FIG. 3A-3C embodiments or the FIG. 4A-4C embodiments. Accordingly, both pairs of electrode reference numbers 312, 322 and 421, 422 are used to designate the electrodes in FIG. 6. The electrode pairs 321, 322 and 421, 422 are separated by a dielectric material from either layer 325 or 312 depending on the fabrication process. Electrically conductive connections 657 and 658 are fabricated through layer 325. Connections 657 and 658 respectively provide electrical communication to individual plates 321 and 322 or 421 and 422 of the capacitor. Connections 657 and 658 connect to further circuitry. In an embodiment, the connections 657 and 658 connect to I/O circuits to provide signal conditioning or electrostatic discharge protection.

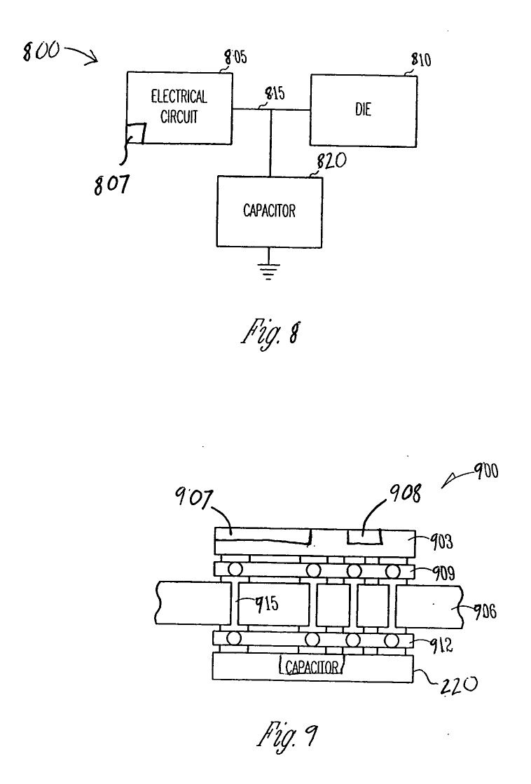

FIG. 7 shows a plan view of an array of capacitors on an interposer substrate. In this embodiment, the dielectric material 715 intermediate the electrodes 321, 322 or 421, 422 is elongate and extends between a plurality of plates of the capacitor. The connections 657 and 658 extend to electrode plates 321, 322 or 421, 422 as described herein. Using an array of capacitors provides the flexibility to provide the capacitance needed for a particular application by connecting only certain groups of the connections 657 and 658 to provide the required capacitance. For required capacitance, the design of electrode could be flexible. In some applications, some of the electrode plates 321, 322 or 421, 422 would remain unconnected to external circuits and hence would not add to the capacitance.

FIG. 8 shows a system 800 including an electrical circuit 805 and a die 810 operably connected together through an interface 815. The electrical circuit includes a wireless communication device 807. Wireless communication device 807 is used to link system 800 with a further electronic system such as a telephone network, local area network, wide area network or the internet. The wireless communication device 807 operates according to orthogonal frequency-division multiplexing (OFDM) in an embodiment. In wireless communications, the OFDM link may be designed to operate according to an Institute of Electrical and Electronic Engineers (IEEE) 802.11 specification, an IEEE 802.15 specification, or an IEEE 802.16 specification. For additional information regarding IEEE 802.11 standards, please refer to “IEEE Standards for Information Technology—Telecommunications and Information Exchange between Systems—Local and Metropolitan Area Network—Specific Requirements—Part 11: Wireless LAN Medium Access Control (MAC) and Physical Layer (PHY), ISO/IEC 8802-11: 1999” and related amendments. In an embodiment, interface 815 includes at least one conductive bonds, traces, conductors, and electrically conductive lines. In an embodiment, interface 815 is a power supply line. In an embodiment, interface 815 is data input/output line(s). In an embodiment, interface 815 is control signal or address line(s). An interposer 820 having a capacitor according to the teachings herein and equivalents is connected to conductive interface 815. In an embodiment, a first group of capacitor first electrodes are connected to interface 815. A second group of capacitor second electrodes are connected to a node separate from interface 815 in the electric circuit 805. In an embodiment, the node is a grounded node. As described in the embodiments above, capacitor 820 includes co-planar electrodes separated laterally by a dielectric. While the electrical circuit 805 is described as including a wireless communication device, electrical circuit may exclude the wireless communication device 807 in favor of a stand alone processor. In an embodiment, the electrical circuit is part of a computer system such as a LAN or WAN. In a further embodiment, wireless communication device 807 is a mobile telephone.

FIG. 9 shows a cross-sectional view of one embodiment of system 900 for coupling a die 903 to co-planar capacitor 920 through common substrate 906. In an embodiment, die 903 includes an electronic device, such as a processor 908, a memory, a communication system 907, or an application specific integrated circuit. Wireless communication device 907 is used to link system die 903 with a further electronic system such as a telephone network, local area network, wide area network or the internet. In an embodiment, device 907 is a cellular telephone receiver or transceiver. Die 903 is coupled to a first surface of substrate 906 by controlled collapse chip connection (C4) 909. It will be recognized by one of skill in the art that other conventional structures may mechanically and electrically connect die 903 to substrate 906. Interposer 220 is coupled to a second surface of substrate 906 by a mechanical or electrical connection 912. Examples of connection 912 include surface mount or controlled collapse chip connection. Conductive interconnects 915 extend from the first surface to the second surface of substrate 906 to couple the capacitor 220 to die 903. In an embodiment, interconnects 915 are formed by filling a via in the substrate 906 with a conductive material, such as metal. In one embodiment, substrate 906 is fabricated from a ceramic material. Alternatively, substrate 906 is fabricated from an organic material. Preferably, substrate 906 is thin, which permits a short coupling distance between the interposer with capacitor 220 and die 903. In one embodiment, substrate 906 has a thickness of less than about 1 millimeter, which reduces the length of interconnects 915. A short coupling distance reduces the inductance and resistance in the circuit in which the interposer 220 is connected. It will also be recognized that the capacitor could be coupled directly to die 903 in an embodiment. While FIG. 9 shows the capacitor on one side of the interposer with the die on the other, it will be recognized that the interposer is between the substrate and die in an embodiment. Such a location is shown in FIG. 2. This type of assembly, with the interposer between the die and package substrate, will result in even shorter distances from the capacitor to the die.

In a further embodiment, the capacitor of an embodiment of the present invention is fabricated as a pre-formed unit that is then laminated to the package. The integrated circuit die is thereafter connected to the capacitor on package. In an embodiment, the integrated circuit die is laminated directly to the capacitor.

The above description is intended to be illustrative, and not restrictive. Many other embodiments will be apparent to those of skill in the art upon reading and understanding the above description. Therefore, the scope of the invention should be determined with reference to the appended claims, along with the full scope of equivalents to which such claims are entitled.

We claim:

1. A method of forming a capacitor, comprising:
providing a ceramic base having a high-k dielectric layer;
forming a first electrode and a second electrode on the high-k dielectric layer such that the first electrode and the second electrode are neither vertically above nor below each other and such that a smallest area surface of the first electrode is adjacent a smallest area surface of the second electrode;
interposing a dielectric wall having a high-k dielectric constant between the first electrode and the second electrode; and
covering the first electrode and the second electrode with a further high-k dielectric layer.

2. The method of claim 1, wherein interposing a dielectric wall includes forming a dielectric layer and etching a first recess and a second recess in the dielectric layer, and wherein forming the first electrode and the second electrode includes filling the first recess with a first conductive material to form the first electrode and filling the second recess with a second conductive material to form the second electrode.

3. The method of claim 2, wherein the first conductive material and the second conductive material are the same.

4. The method of claim 3, wherein at least one of the first conductive material and the second conductive material includes platinum.

5. The method of claim 3, wherein the dielectric wall includes barium strontium titanate.

6. The method of claim 1, wherein forming a first electrode and a second electrode includes forming the first and second electrodes simultaneously on the high-k dielectric layer and forming a gap interposed between the first electrode and the second electrode, and wherein interposing a dielectric wall includes filling the gap while covering the first electrode and the second electrode with the further high-k dielectric layer.

7. The method of claim 6, wherein forming the first electrode and the second electrode include forming essentially co-planar top surfaces of the first electrode and the second electrode, and co-planar bottom surfaces of the first electrode and the second electrode.

8. The method of claim 7, wherein forming the first electrode includes forming the first electrode to have a thickness of less than about 20 μm.

9. The method of claim 1, wherein forming a first electrode and a second electrode includes positioning a surface of greatest area of the first electrode to be parallel to an upper surface of the ceramic base and positioning a surface of greatest area of the second electrode to be parallel to the upper surface of the ceramic base.

10. A method of forming a capacitor, comprising:
forming a high-k dielectric layer on a substrate;
simultaneously forming a first electrode and a second electrode on the high-k dielectric layer such that the first electrode has a first surface of greatest area of the first electrode to be parallel to an upper surface of the substrate and a second surface of greatest area of the second electrode to be parallel to the upper surface of the substrate;
interposing between the first electrode and the second electrode a barium strontium titanate dielectric wall; and
interconnecting the first electrode and the second electrode to further circuitry.

11. The method of claim 9, wherein the dielectric wall includes vertical defects that do not electrically short the first and second electrodes.

12. The method of claim 11, wherein interconnecting includes connecting the first electrode to an input/output line of an electrical circuit.

13. The method of claim 12, wherein the input/output line is connected to an integrated circuit.

14. The method of claim 9, wherein interposing between the first electrode and the second electrode a barium strontium titanate dielectric wall is performed before simultaneously forming the first electrode and the second electrode, and wherein interposing between includes treating the barium strontium titanate dielectric wall in an oxygen environment.

15. The method of claim 9, wherein the first electrode and the second electrode each include platinum.

16. An thin film capacitor structure, comprising:
a substrate;
a high-k dielectric layer supported by the substrate;
a first electrode on the high-k dielectric layer;
a second electrode on the high-k dielectric layer horizontally spaced from the first electrode;
a high-k dielectric wall interposed between the first electrode and second electrode; and
a further high-k dielectric layer covering the first electrode and the second electrode.

17. The structure of claim 16, wherein the wall has a thickness of about 90 μm.

18. The structure of claim 16, wherein the first electrode is connected to an input/output signal line.

19. The structure of claim 16, wherein the substrate is adapted to connect to further electrical circuitry.

20. The structure of claim 16, wherein the first electrode and the second electrode include platinum.

21. A system, comprising:
an electrical circuit having a wireless communication device;
a film capacitor operably connected to the electrical circuit, the capacitor including:
a substrate;
a high-k dielectric layer supported by the substrate;
a first electrode on the high-k dielectric layer;
a second electrode on the high-k dielectric layer horizontally spaced from the first electrode;
a high-k dielectric wall interposed between the first electrode and second electrode; and
a further high-k dielectric layer covering the first electrode and the second electrode.

22. The system according to claim 21, wherein the electrical circuit includes a processor.

23. The system according to claim 21, wherein the wireless communication device is adapted to communicate using the IEEE 802.11 standard.
